(19) United States
(12) Patent Application Publication
(10) Pub. No.: US 2024/0312801 A1
(43) Pub. Date: Sep. 19, 2024

(54) SEMICONDUCTOR MANUFACTURING APPARATUS AND METHOD FOR MANUFACTURING SEMICONDUCTOR DEVICE

(71) Applicant: Kioxia Corporation, Tokyo (JP)

(72) Inventor: Shohei ARAKAWA, Mie Mie (JP)

(21) Appl. No.: 18/586,372

(22) Filed: Feb. 23, 2024

(30) Foreign Application Priority Data
Mar. 15, 2023 (JP) 2023-041266

(51) Int. Cl. H01L 21/67; H01J 37/32; H01L 21/306; H01L 21/3065

(52) U.S. Cl. CPC H01L 21/67069; H01J 37/3244; H01J 37/32522; H01J 37/32642; H01J 37/32743; H01J 37/32899; H01L 21/30604; H01L 21/3065; H01J 2237/002; H01J 2237/3341

(57) ABSTRACT

A semiconductor manufacturing apparatus includes a bevel processing chamber, a stage on which a first surface of a substrate is to be placed, a first gas supply pipe configured to supply first gas to a first surface side of the substrate, a first ring surrounding the stage and having an outer diameter smaller than a diameter of the substrate, a top plate facing a second surface of the substrate, a second gas supply pipe configured to supply second gas to a second surface side of the substrate, a second ring surrounding the top plate and having an outer diameter smaller than the diameter of the substrate, a first electrode surrounding the first ring, a second electrode surrounding the second ring, a third gas supply pipe configured to supply process gas, and a control circuit that controls plasma processing of a bevel of the substrate using the process gas.

### CROSS-REFERENCE TO RELATED APPLICATION(S)

This application is based upon and claims the benefit of priority from Japanese Patent Application No. 2023-041266, filed Mar. 15, 2023, the entire contents of which are incorporated herein by reference.

### FIELD

Embodiments described herein relate generally to a semiconductor manufacturing apparatus and a method for manufacturing a semiconductor device.

### BACKGROUND

As a semiconductor manufacturing apparatus, a bevel processing apparatus is known which performs plasma processing on a film deposited on a bevel (peripheral edge portion) of a substrate. When a non-volatile by-product generated by the plasma processing adheres to a top plate of the bevel processing apparatus, a downtime is required to carry out a process for wiping off a residual.

### DESCRIPTION OF THE DRAWINGS

FIG. 1 is a configuration diagram of a semiconductor manufacturing apparatus according to a first embodiment.

FIG. 2 is a plan view of a top plate, an upper quartz ring, and an upper electrode which are provided in the semiconductor manufacturing apparatus according to the first embodiment.

FIG. 3 is a conceptual diagram of bevel etching using the semiconductor manufacturing apparatus according to the first embodiment.

FIG. 4 is a flowchart showing a flow of the bevel etching in a method for manufacturing a semiconductor device according to the first embodiment.

FIG. 5 is a flowchart showing a flow of plasma processing using the semiconductor manufacturing apparatus according to the first embodiment.

FIG. 6 is a plan view showing a configuration of a semiconductor manufacturing apparatus according to a second embodiment.

FIG. 7 is a flowchart showing an example of a flow of plasma processing in the semiconductor manufacturing apparatus according to the second embodiment.

FIG. 8 is an apparatus plan view showing movement of a semiconductor substrate in the semiconductor manufacturing apparatus according to the second embodiment.

### DETAILED DESCRIPTION

Embodiments provide a semiconductor manufacturing apparatus and a method for manufacturing a semiconductor device which can improve throughput.

In general, according to one embodiment, there is provided a semiconductor manufacturing apparatus including a bevel processing chamber, a stage provided in the bevel processing chamber, on which a substrate is to be placed, and configured to come into contact with a first surface of the substrate, a first gas supply pipe configured to supply a first gas to a first surface side of the substrate to cool a bevel of the substrate, a first ring surrounding the stage and having an outer diameter smaller than a diameter of the substrate, a top plate provided in the bevel processing chamber and facing a second surface of the substrate that is on an opposite side of the substrate with respect to the first surface, a second gas supply pipe configured to supply a second gas to a second surface side of the substrate to cool the bevel of the substrate, a second ring surrounding the top plate and having an outer diameter smaller than the diameter of the substrate, a first electrode surrounding the first ring, a second electrode surrounding the second ring, a third gas supply pipe configured to supply a process gas used for plasma processing of the bevel, and a control circuit that controls the plasma processing of the bevel.

Hereinafter, embodiments will be described with reference to drawings. In the following description, the same reference numerals will be assigned to elements having substantially the same functions and configurations, and repeated description will be given when necessary. In addition, each of the embodiments described below is an example of devices or methods for embodying the technical idea of the embodiment, and a material, a shape, a structure, and a disposition of components are not limited to those which are described below.

### 1. First Embodiment

A semiconductor manufacturing apparatus according to a first embodiment will be described. Hereinafter, as the semiconductor manufacturing apparatus, a bevel processing apparatus that performs reduction processing on a compound deposited on a bevel (peripheral edge portion) of a semiconductor substrate (e.g., silicon wafer) in a plasma atmosphere will be described. Processing in the plasma atmosphere is not limited to the reduction processing. The bevel processing apparatus may perform an etching process, or may perform oxidation processing on the compound deposited on the bevel of the silicon substrate in the plasma atmosphere.

Hereinafter, a case where the compound contains In will be described. Examples of compounds containing In include non-metallic elements or semi-metallic elements out of Group 15 elements, Group 16 elements, and Group 17 elements, such as oxygen (O), phosphorus (P), boron (B), carbon (C), nitrogen (N), silicon (Si), sulfur (S), selenium (Se), tellurium (Te), fluorine (F), chlorine (CI), bromine (Br), or iodine (I), and compounds with In. Specific examples of the compounds include In oxide (InO), In phosphide (InP), In nitride (InN), In arsenide (InAs), and In selenide (InSe). The compounds containing In can contain at least one of these materials. Meanwhile, the compounds containing In may also contain metal elements other than In, for example, such as tin (Sn), gallium (Ga), aluminum (Al), and zinc (Zn).

The compounds containing In such as In oxide and In phosphide may function as semiconductors or conductors. Examples of oxide containing In include indium tin oxide (ITO), indium-gallium-zinc oxide (In—Ga—Zn oxide: IGZO), indium-aluminum-zinc oxide (In—Al—Zn Oxide: IAZO), and indium oxide (InO).

The oxide containing In such as ITO having a high proportion of In oxide has the following disadvantages. The oxide is highly resistant to acidic and alkaline chemicals used for wet etching. Furthermore, processing residues or non-volatile substances are likely to be generated with respect to halogen-based gases (HBr or Cl₂) or organic gases (CH₄, CH₃OH, CF₄, CHF₃) used for dry etching. Therefore, it is difficult to efficiently etch the oxide containing In without generating the processing residues or the like. Therefore, reduction processing performed by the bevel processing apparatus of the present embodiment is applied as preprocessing for performing bevel etching on the oxide containing In.

### 1.1 Configuration of Bevel Processing Apparatus

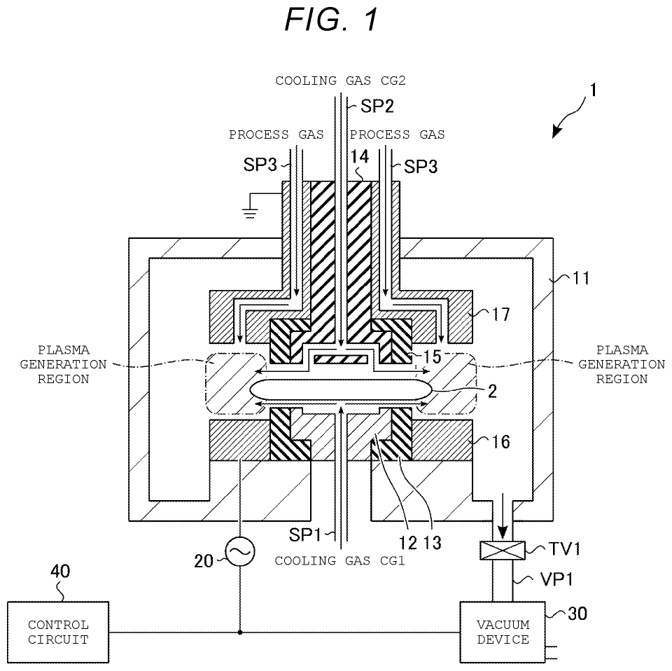

First, an example of a configuration of the bevel processing apparatus 1 will be described with reference to FIG. 1. FIG. 1 is a configuration diagram of the bevel processing apparatus 1. In the following description, when a front surface of the semiconductor substrate 2 or a back surface of the semiconductor substrate 2 are described, the bevel of the semiconductor substrate 2 is not included.

As shown in FIG. 1, the bevel processing apparatus 1 includes a chamber 11, a stage 12, a lower quartz ring 13, a top plate 14, an upper quartz ring 15, a lower electrode 16, an upper electrode 17, a high frequency power source 20, a vacuum device 30, a control circuit 40, a throttle valve TV, gas supply pipes SP1 to SP3, and an evacuation pipe VP1.

The chamber 11 is a processing chamber used for bevel plasma processing. For example, an internal pressure of the chamber 11 is maintained at a low pressure (i.e., pressure lower than an atmospheric pressure). The gas in the chamber 11 is evacuated via the evacuation pipe VP1. For example, the chamber 11 can be managed at a proper temperature by a temperature control mechanism (not shown). For example, a gate valve (not shown) is provided in the chamber 11. The semiconductor substrate 2 is conveyed into the inside of the chamber 11 from outside of the chamber 11 via the gate valve.

The stage 12 is provided at a lower side inside the chamber 11. The stage 12 supports the semiconductor substrate 2 placed thereon. An upper surface of the stage 12 is in contact with a back surface of the semiconductor substrate 2. The upper surface of the stage 12 has a circular shape. A diameter of the upper surface of the stage 12 is smaller than a diameter of the semiconductor substrate 2. For example, the stage 12 has an electrostatic chuck function, and fixes a position of the semiconductor substrate 2 placed on the stage 12. In this case, the stage 12 is connected to a high frequency power source (not shown) for controlling the electrostatic chuck. The stage 12 may include a thermocouple for temperature measurement. In addition, the stage 12 may have a mechanism for lifting up the semiconductor substrate 2.

The stage 12 is provided with an internally penetrating gas supply pipe SP1. The stage 12 supplies a cooling gas CG1 to the back surface of the semiconductor substrate 2 via the gas supply pipe SP1. As the cooling gas CG1, for example, a gas containing at least one gas selected from the group including rare gases such as helium (He), neon (Ne), and argon (Ar) is used. In addition, the cooling gas CG1 may be the same as the process gas, or may be a mixed gas of the process gas and the rare gas. The stage 12 is cooled by the cooling gas CG1. In addition, the bevel of the semiconductor substrate 2 is cooled by the cooling gas CG1 from the back surface side of the semiconductor substrate 2. For example, it is preferable that the stage 12 is cooled to 0° C. or higher and 60° C. or lower by using the cooling gas CG1 during the plasma processing. In other words, it is preferable that the bevel of the semiconductor substrate 2 is cooled to a temperature of 0° C. or higher and 60° C. or lower. For example, when ITO deposited on the bevel is subjected to reduction processing (plasma processing) at a temperature exceeding 60° C., surface morphology of a modified layer of reduced ITO deteriorates due to aggregation of In contained in ITO. Therefore, removability of ITO deteriorates in the wet etching after the reduction processing. In addition, when ITO deposited on the bevel is subjected to reduction processing at a temperature below 0° C., an advantageous effect of the reduction processing is weakened, and a modified layer of ITO is less likely to be formed. Therefore, removability of ITO deteriorates in the wet etching after the reduction processing.

The lower quartz ring 13 surrounds a side surface of the stage 12. The lower quartz ring 13 insulates the stage 12 and the lower electrode 16. In addition, the lower quartz ring 13 prevents the back surface of the semiconductor substrate 2 and the stage 12 from being exposed to the plasma atmosphere during the plasma processing. An outer diameter of the lower quartz ring 13 is smaller than a diameter of the semiconductor substrate 2. In this manner, the bevel of the semiconductor substrate 2 protrudes outward (in a lateral direction) from an outer periphery of the lower quartz ring 13.

The top plate 14 is provided at an upper side of the chamber 11. For example, as the top plate 14, a material having excellent insulation properties such as aluminum oxide (Al₂O₃) or yttrium oxide (Y₂O₃) can be used. A lower surface of the top plate 14 faces the front surface of the semiconductor substrate 2. That is, the lower surface of the top plate 14 faces an upper surface of the stage 12. The lower surface of the top plate 14 has a circular shape. The diameter of the lower surface of the top plate 14 is smaller than the diameter of the semiconductor substrate 2. In order to eliminate electrons or ions generated by plasma, a distance from the lower surface of the top plate 14 to the front surface of the semiconductor substrate 2 is set to be smaller than a distance between the upper electrode 17 and the lower electrode 16 (for example, 0.35 mm or more and 0.55 mm or less). In this manner, the bevel plasma processing can be performed without generating plasma on the front surface of the semiconductor substrate 2.

The top plate 14 is provided with an internally penetrating gas supply pipe SP2. The top plate 14 supplies a cooling gas CG2 to the front surface and the bevel of the semiconductor substrate 2 via the gas supply pipe SP2. The top plate 14 is cooled by the cooling gas CG2. In addition, the bevel of the semiconductor substrate 2 is cooled from the front surface side of the semiconductor substrate 2 by the cooling gas CG2. For example, as in the stage 12, it is preferable that the top plate 14 is cooled to a temperature of 0° C. or higher and 60° C. or lower by the cooling gas CG2. In addition, since the cooling gas CG2 is supplied into the chamber 11 from the top plate 14, by-products generated by the plasma processing can be prevented from diffusing between the top plate 14 and the semiconductor substrate 2. In this manner, the by-products can be prevented from adhering to the top plate 14. As the cooling gas CG2, for example, a gas containing at least one gas selected from the group including the rare gases such as He, Ne, and Ar is used. In addition, the cooling gas CG2 may be the same as the process gas, or may be a mixed gas of the process gas and the rare gas. The cooling gas CG2 may be of the same type as, or may be different from the cooling gas CG1. The bevel processing apparatus 1 has a mechanism for cooling the gas, and this mechanism may generate the cooling gas CG1 and the cooling gas CG2.

The upper quartz ring 15 surrounds a lower side of a side surface of the top plate 14. The upper quartz ring 15 prevents the front surface of the semiconductor substrate 2 and the top plate 14 from being exposed to the plasma atmosphere during the plasma processing. In order to cause the bevel of the semiconductor substrate 2 to protrude outward from the outer periphery of the upper quartz ring 15, the outer diameter of the upper quartz ring 15 is smaller than the diameter of the semiconductor substrate 2. The outer diameter of the upper quartz ring 15 is approximately the same as the outer diameter of the lower quartz ring 13.

The lower electrode 16 surrounds the stage 12 and the lower quartz ring 13. For example, the upper surface of the lower electrode 16 has an annular shape. An inner diameter of the upper surface of the lower electrode 16 is smaller than the diameter of the semiconductor substrate 2. The outer diameter of the upper surface of the lower electrode 16 is larger than the diameter of the semiconductor substrate 2. A height position of the upper surface of the lower electrode 16 is lower than a height position of the upper surfaces of the stage 12 and the lower quartz ring 13. The lower electrode 16 is insulated from the chamber 11 and the stage 12.

The upper electrode 17 surrounds the top plate 14 and the upper quartz ring 15. The lower surface of the upper electrode 17 faces the upper surface of the lower electrode 16, and the surfaces are parallel to each other. A shape of the lower surface of the upper electrode 17 is approximately the same as a shape of the upper surface of the lower electrode 16. As in the lower electrode 16, the inner diameter of the lower surface of the upper electrode 17 is smaller than the diameter of the semiconductor substrate 2. The outer diameter of the lower surface of the upper electrode 17 is larger than the diameter of the semiconductor substrate 2. The bevel of the semiconductor substrate 2 protruding from between the upper quartz ring 15 and the lower quartz ring 13 is located between the lower electrode 16 and the upper electrode 17. The height position of the lower surface of the upper electrode 17 is higher than the height positions of the lower surface of the top plate 14 and the lower surface of the upper quartz ring 15. The upper electrode 17 is insulated from the chamber 11. A region between the lower electrode 16 and the upper electrode 17 is a plasma generation region in the plasma processing. When plasma is generated, the bevel of the semiconductor substrate 2 is exposed to the plasma atmosphere.

The upper electrode 17 is provided with an internally penetrating gas supply pipe SP3. The upper electrode 17 supplies the process gas to a region between the upper electrode 17 and the lower electrode 16 via the gas supply pipe SP3. That is, the upper electrode 17 supplies the process gas to the bevel of the semiconductor substrate 2. In the present embodiment, a reduction gas is supplied as the process gas used for the plasma processing. For example, the reduction gas includes gases containing hydrogen atoms (H). As the reduction gas, a gas containing at least one gas selected from the group including hydrogen (H₂), ammonia (NH₃), hydrogen sulfide (H₂S), and water vapor (H₂O) is used. Any gas containing these materials can be applied to the reduction processing of the compound containing In. In addition to these gases, hydrogen fluoride (HF), hydrogen chloride (HCl), hydrogen bromide (HBr), hydrogen iodide (HI), methane (CH₄), trifluoromethane (CHF₃), difluoromethane (CH₂F₂), and fluoromethane (CH₃F) can be used.

The high frequency power source 20 generates plasma discharge between the lower electrode 16 and the upper electrode 17. Hereinafter, a case where the plasma discharge is generated will also be referred to as “bringing plasma into an on-state”. The plasma discharge activates the process gas. The high frequency power source 20 is connected to the lower electrode 16. The upper electrode 17 facing the lower electrode is grounded. The high frequency power source 20 may be connected to the upper electrode 17, and the lower electrode 16 may be grounded.

The evacuation pipe VP1 is connected to an evacuation port of the chamber 11 via the throttle valve TV. The throttle valve TV can adjust an opening degree of a valve, and is used for pressure control of the chamber 11. A temperature control mechanism (not shown) may be attached to the evacuation pipe VP1 to prevent adhesion of the by-products.

The vacuum device 30 evacuates the gas inside the chamber 11 via the evacuation pipe VP1. A configuration of the vacuum device 30 is based on processing conditions. For example, the vacuum device 30 may have a configuration in which a mechanical booster pump is provided on an upstream side of the evacuation gas and a dry pump is provided on a downstream side.

The control circuit 40 controls the entire bevel processing apparatus 1. The control circuit 40 performs the plasma processing in the bevel processing apparatus 1. For example, the high frequency power source 20, the vacuum device 30, and the throttle valve TV are controlled. More specifically, the control circuit 40 controls loading and unloading of the semiconductor substrate 2 into and from the chamber 11, supply and evacuation of various gases to and from the chamber 11, the plasma discharge performed by the high frequency power source 20, the electrostatic chuck of the stage 12, the pressure of the chamber 11, and the temperature of the stage 12.

### 1.2 Planar Configuration of Top Plate

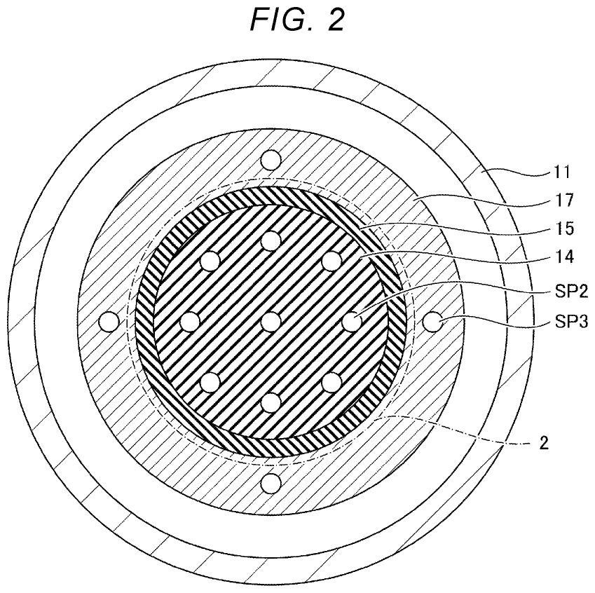

Next, an example of a planar configuration of the top plate will be described with reference to FIG. 2. FIG. 2 is a plan view when the lower surface of the top plate 14, the upper quartz ring 15, and the upper electrode 17 are viewed from below the chamber 11.

As shown in FIG. 2, the top plate 14 is provided with gas ejection ports of a plurality of the gas supply pipes SP2. In the example in FIG. 2, one gas ejection port is provided at a center of the top plate 14, and eight gas ejection ports are concentrically provided at an equal interval. The number and disposition of the gas ejection ports of the gas supply pipe SP2 provided in the top plate 14 may be determined in any way.

The upper quartz ring 15 having an annular shape surrounds the top plate 14. The outer diameter of the upper quartz ring 15 is smaller than the diameter of the semiconductor substrate 2. The bevel of the semiconductor substrate 2 protrudes outward from the outer periphery of the upper quartz ring 15.

The upper electrode 17 having an annular shape surrounds the outer periphery of the upper quartz ring 15. The upper electrode 17 is provided with gas ejection ports of a plurality of the gas supply pipes SP3. In the example in FIG. 2, four gas ejection ports are concentrically provided at an equal interval. The number and disposition of the gas ejection ports of the gas supply pipe SP3 provided in the upper quartz ring 15 may be determined in any way.

### 1.3 Bevel Etching Process

### 1.3.1 Overview of Bevel Etching Process

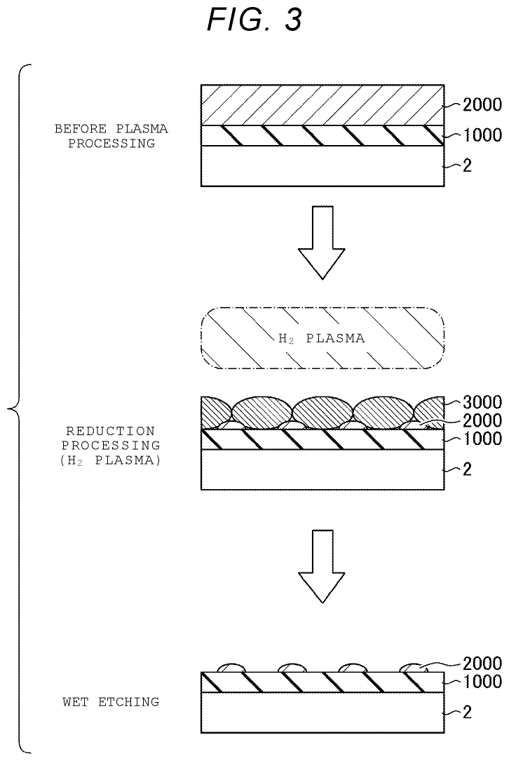

First, an overview of a bevel etching process will be described with reference to FIG. 3. FIG. 3 is a conceptual diagram of bevel etching using the bevel processing apparatus 1. In an example in FIG. 3, a case of removing ITO formed on a silicon oxide film will be described. The semiconductor substrate 2 shown in FIG. 3 is shown by partially enlarging the bevel.

As shown in FIG. 3, a silicon oxide film (SiO₂) 1000 is formed on the semiconductor substrate 2. Furthermore, a film of an etching target compound (ITO) 2000 is formed on SiO₂. In this state, a bevel etching process is performed to remove the compound 2000 of the bevel.

The etching process includes reduction processing and wet etching. The reduction processing is performed in the bevel processing apparatus 1.

The reduction processing is a process of reducing the surface of the compound 2000 (eliminating oxygen). Oxygen is eliminated from compound 2000 by the reduction processing. In this manner, a modified layer 3000 modified by the reduction processing (from which oxygen is eliminated) is formed on the silicon oxide film 1000. In this case, deterioration of the surface morphology of the modified layer 3000 can be prevented by controlling a processing temperature of the reduction processing in a range of 0° C. to 60° C. The modified layer 3000 is excellent in workability, compared to compound 2000. Therefore, the modified layer 3000 can be efficiently processed with a chemical solution such as a wet etching solution, and the processing residues can be prevented.

The wet etching is a process of etching the modified layer 3000. The wet etching is performed by a wet etching apparatus (not shown). For example, the chemical solution used for wet etching includes at least one of the group including hydrochloric acid (HCl), hydrofluoric acid (HF), and nitric acid (HNO₃). More specifically, as the chemical solution, the following acid solutions are used. For example, the acid solutions include an aqueous solution in which hydrochloric acid (HCl) is approximately 0.5% by mass or more and 40% by mass or less, an aqueous solution in which hydrofluoric acid (HF) is approximately 0.01% by mass or more and 50% by mass or less, a mixture in which hydrochloric acid (HCl) of 30% by mass or more and nitric acid (HNO₃) of 70% by mass or less are mixed, and a mixed solution in which the mixture is diluted with water (H₂O) in any proportion of 10% by volume or more. Processing the modified layer 3000 is processed with the acid solution, the modified layer 3000 can be etched and removed. Depending on a type of the modified layer 3000, an alkaline solution may be used as the chemical solution.

For example, it is difficult to process the oxide containing In when crystallized. Therefore, an etching method of the present embodiment is more effectively used when a processing target compound such as the oxide containing In includes a crystallized portion.

### 1.3.2 Flow of Bevel Etching

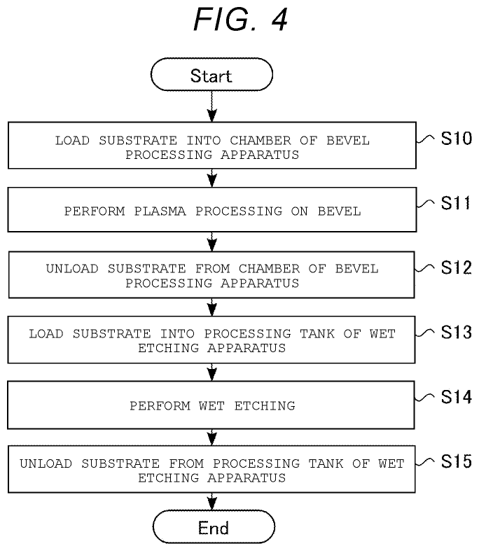

Next, a flow of the bevel etching process will be described with reference to FIG. 4. FIG. 4 is a flowchart showing a flow of bevel etching.

As shown in FIG. 4, first, the semiconductor substrate 2 on which the compound 2000 is formed is loaded into the chamber 11 of the bevel processing apparatus 1 (S10).

The control circuit 40 performs the bevel plasma processing (reduction processing) in the chamber 11 (S11). In this case, in a state where the bevel is cooled by supplying the cooling gas CG1 from the stage 12 (back surface side of the semiconductor substrate 2) and supplying the cooling gas CG2 from the top plate 14 (front surface side of the semiconductor substrate 2), the bevel plasma processing is performed. In this manner, the modified layer 3000 is formed on the bevel of the semiconductor substrate 2. In this case, the plasma discharge is not generated between the front surface of the semiconductor substrate 2 and the top plate 14. Therefore, the modified layer 3000 is not formed on the front surface of the semiconductor substrate 2. Details of a flow of the plasma processing in the bevel processing apparatus 1 will be described later.

After the plasma processing is completed, the semiconductor substrate 2 is unloaded from the chamber 11 of the bevel processing apparatus 1 (S12).

Next, the semiconductor substrate 2 on which the modified layer 3000 is formed (after the reduction processing is completed) is loaded into a processing tank of the wet etching apparatus (S13). A type of the wet etching apparatus is not limited. For example, the wet etching apparatus may be of a batch type that processes a plurality of the semiconductor substrates 2 altogether, or may be a single wafer type that processes a plurality of the semiconductor substrates 2 one by one. Furthermore, the wet etching apparatus may be a spin etching apparatus configured to supply the chemical solution only to the bevel of the semiconductor substrate 2.

The wet etching of the modified layer 3000 is performed (S14).

After the wet etching is completed, the semiconductor substrate 2 is unloaded from the wet etching apparatus (S15), and the bevel etching is completed.

In the bevel etching process, a loop including the reduction processing and the wet etching process may be repeatedly performed multiple times.

### 1.4 Flow of Plasma Processing in Bevel Processing Apparatus

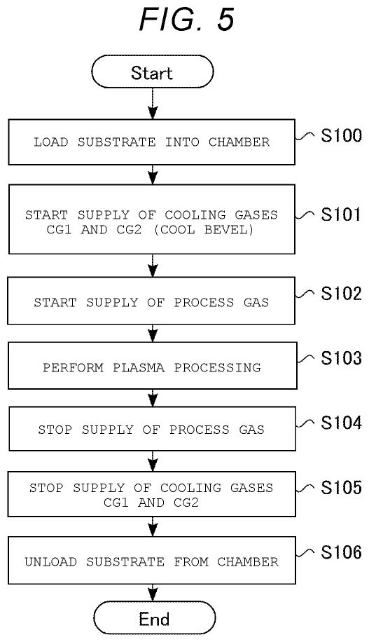

Next, an example of a flow of plasma processing in the bevel processing apparatus 1 will be described with reference to FIG. 5. FIG. 5 is a flowchart showing the flow of the plasma processing using the bevel processing apparatus 1. FIG. 5 corresponds to S10 to S12 in FIG. 4.

As shown in FIG. 5, first, the control circuit 40 loads the semiconductor substrate 2 into the chamber 11 (S100). For example, the control circuit 40 controls a gate valve and a conveyance mechanism of the semiconductor substrate 2, and places the semiconductor substrate 2 on the stage 12. The control circuit 40 brings the electrostatic chuck of the stage 12 into an on-state, and fixes the position of the semiconductor substrate 2 on the stage 12.

The control circuit 40 starts the supply of the cooling gas CG1 and the supply of the cooling gas CG2 in a state where the semiconductor substrate 2 is placed on the stage 12 (S101). For example, He is supplied as the cooling gas CG1 and the cooling gas CG2. The bevel of the semiconductor substrate 2 is cooled by the cooling gas CG1 and the cooling gas CG2. In this case, the temperature of the stage 12 is controlled to be 0° C. or higher and 60° C. or lower. Supply start timings and supply end timings of the cooling gas CG1 and the cooling gas CG2 may coincide with each other, or only any one of the supply start timings and the supply end timings may coincide with each other. Furthermore, although the time for supplying the cooling gas CG1 and the cooling gas CG2 is the same, the supply start timings and the supply end timings of the cooling gas CG1 and the cooling gas CG2 may be different from each other.

The control circuit 40 starts the supply of the process gas (for example, H₂) in a state where the cooling gas CG1 and the cooling gas CG2 are supplied (S102). The control circuit 40 controls an opening degree of the throttle valve TV, and sets the pressure in the chamber 11 in advance to perform the plasma processing. When the cooling gas CG1 and/or the cooling gas CG2 are the same as the process gas, S101 and S102 can be at least partially merged. For example, hydrogen (H₂) can be used for the cooling gas CG1 or the cooling gas CG2.

The control circuit 40 controls the high frequency power source 20, and generates the plasma discharge in a region including the bevel. In this case, the plasma discharge is not generated between the front surface of the semiconductor substrate 2 and the top plate 14. In this manner, the plasma processing (reduction processing using H₂ plasma) is performed on the bevel (S103). After the plasma processing is completed, the control circuit 40 brings the high frequency power source 20 into an off-state. For example, the control circuit 40 sets the opening degree of the throttle valve TV to 100%, and evacuates the gas from the chamber 11.

The control circuit 40 stops the supply of the process gas (S104).

Next, the control circuit 40 stops the supply of the cooling gas CG1 and the cooling gas CG2 (S105).

The control circuit 40 brings the electrostatic chuck of the stage 12 into an off-state. Next, for example, the control circuit 40 controls the gate valve and the conveyance mechanism of the semiconductor substrate 2, and unloads the semiconductor substrate 2 from the chamber 11 (S106).

### 1.5 Advantageous Effects of Present Embodiment

The configuration according to the present embodiment can provide a bevel processing apparatus which can improve throughput. These advantageous effects will be described in detail.

For example, when the plasma processing is performed on the oxide containing In deposited on the bevel of the semiconductor substrate, the by-products generated by the plasma processing adhere to a portion of the top plate of the chamber. Therefore, it is necessary to clean the chamber by periodically opening the chamber to atmosphere. In this manner, a downtime of the apparatus is lengthened, and throughput of the apparatus is degraded. In addition, in the reduction processing of the oxide containing In, when the temperature of the semiconductor substrate (in particular, the bevel portion) increases, the modified layer containing In aggregates, and the surface morphology deteriorates. Therefore, when the wet etching is performed on the modified layer, there is a high possibility that the modified layer remains.

In contrast, the configuration according to the present embodiment can supply the cooling gas from the top plate 14 to the bevel of the semiconductor substrate 2. In this manner, the by-products of the plasma processing can be prevented from adhering to the top plate 14. Therefore, the chamber can be cleaned less frequently. Therefore, the throughput of the bevel processing apparatus can be improved by reducing the downtime of the bevel processing apparatus.

Furthermore, the configuration according to the present embodiment can supply the cooling gas from the stage 12 and the top plate 14 to the bevel of the semiconductor substrate 2. That is, the bevel can be cooled from both sides of the back surface and the front surface of the semiconductor substrate 2. A bevel portion can be more efficiently cooled, compared to when the cooling gas is supplied only from either the back surface or the front surface. By cooling the bevel portion, deterioration of the surface morphology of the modified layer can be prevented when the oxide containing In is subjected to the reduction processing in the bevel processing apparatus 1. Therefore, a possibility that the modified layer remains in the subsequent wet etching can be reduced. Therefore, performance for removing compounds in the bevel etching process can be improved.

### 2. Second Embodiment

Next, a second embodiment will be described. In the second embodiment, a semiconductor manufacturing apparatus in which the chamber 11 of the bevel processing apparatus 1 described in the first embodiment is installed will be described.

### 2.1 Configuration of Semiconductor Manufacturing

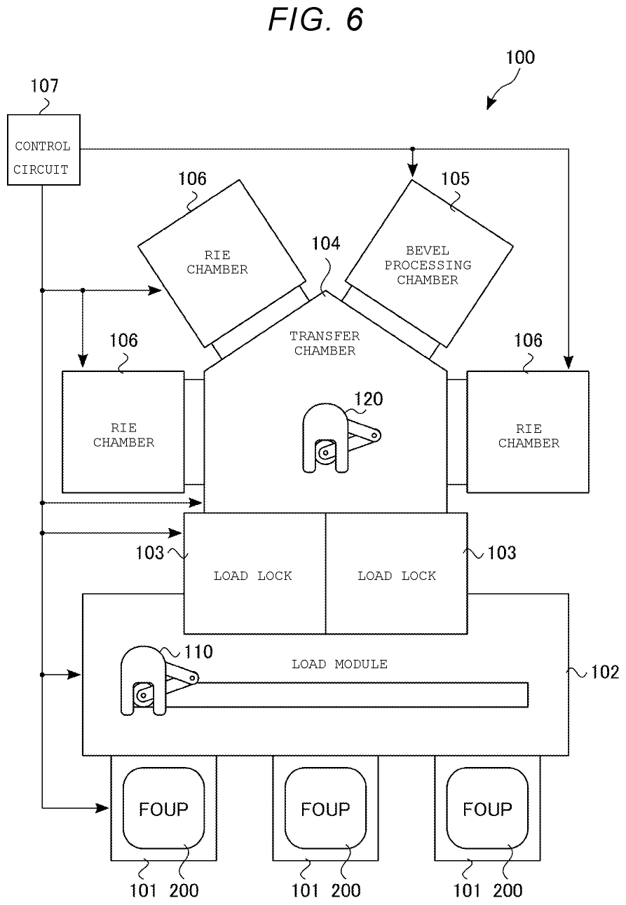

First, an example of the configuration of the semiconductor manufacturing apparatus 100 will be described with reference to FIG. 6. FIG. 6 is a plan view showing the configuration of the semiconductor manufacturing apparatus 100.

As shown in FIG. 6, the semiconductor manufacturing apparatus 100 includes a load port 101, a load module 102, a load lock 103, a transfer chamber 104, a bevel processing chamber 105, a reactive ion etching (RIE) chamber 106, and a control circuit 107.

The load port 101 opens and closes a front opening unified pod (FOUP) 200, for example. The FOUP 200 is set on the load port 101. The FOUP 200 is an airtight container for conveying the semiconductor substrate 2. The FOUP 200 can accommodate a plurality of the semiconductor substrates 2. In an example in FIG. 6 shows a case where three load ports 101 are disposed. Meanwhile, the number of the load ports 101 may be one or more.

The load module 102 includes a handler 110. The handler 110 is drivable so that the semiconductor substrate 2 can be conveyed between the FOUP 200 and the load lock 103.

The load lock 103 is a vacuum chamber for conveying the semiconductor substrate 2 into a vacuum (low pressure) atmosphere. For example, when the semiconductor substrate 2 is conveyed to and from the FOUP 200, the load lock 103 is set at the atmospheric pressure. On the other hand, when the semiconductor substrate 2 is conveyed to and from the transfer chamber 104, the load lock 103 is set in the vacuum (low pressure) atmosphere. The load lock 103 is connected to a vacuum device (not shown). An example in FIG. 6 shows a case where two load locks 103 are disposed. Meanwhile, the number of the load locks 103 may be one or more.

The transfer chamber 104 includes a handler 120. The transfer chamber 104 is connected to the load lock 103, the bevel processing chamber 105, and the RIE chamber 106. The handler 120 is drivable so that the semiconductor substrate 2 can be conveyed to the load lock 103, the bevel processing chamber 105, and the RIE chamber 106. The transfer chamber 104 is maintained in a vacuum atmosphere. The transfer chamber 104 is connected to a vacuum device (not shown).

The bevel processing chamber 105 corresponds to the chamber 11 described in the first embodiment. An example in FIG. 6 shows a case where one bevel processing chamber 105 is disposed. Meanwhile, the number of the bevel processing chambers 105 may be one or more.

The RIE chamber 106 is a chamber for performing dry etching on the semiconductor substrate 2. For example, the RIE chamber 106 can perform the plasma processing on the front surface of the semiconductor substrate 2 under the same plasma processing conditions (gas condition, pressure, RF power, and the like) as those of the bevel processing chamber 105. More specifically, for example, the modified layer 3000 can be formed on the front surface of the semiconductor substrate 2 by performing the reduction processing on the compound 2000 formed on the front surface of the semiconductor substrate 2. In addition, the RIE chamber 106 may have a function of etching the modified layer 3000. For example, an etching gas for etching the modified layer 3000 may be supplied. The example in FIG. 6 shows a case where three RIE chambers 106 are disposed. Meanwhile, the number of the RIE chambers 106 may be one or more.

The control circuit 107 controls the load port 101, the load module 102, the load lock 103, the transfer chamber 104, the bevel processing chamber 105, and the RIE chamber 106. The control circuit 107 performs various processes in the bevel processing chamber 105 and the RIE chamber 106. The control circuit 107 corresponds to the control circuit 40 described in the first embodiment.

The configuration of the semiconductor manufacturing apparatus 100 is not limited thereto. For example, a process chamber different from the bevel processing chamber 105 and the RIE chamber 106 may be provided as the process chamber.

### 2.2 Flow of Plasma Processing in Semiconductor Manufacturing Apparatus

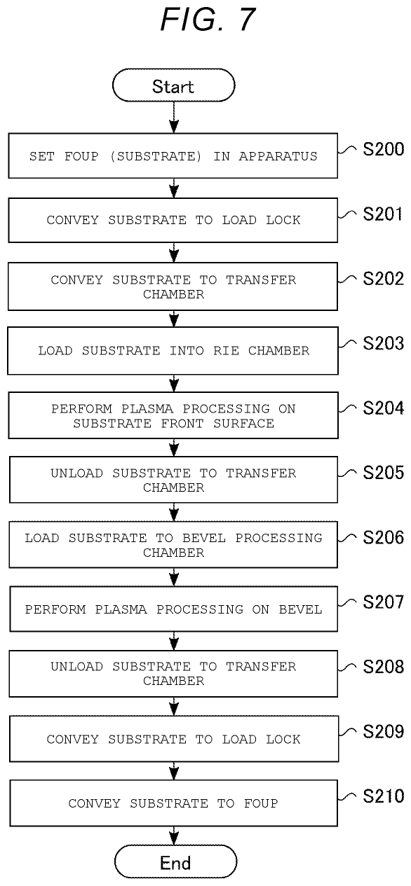

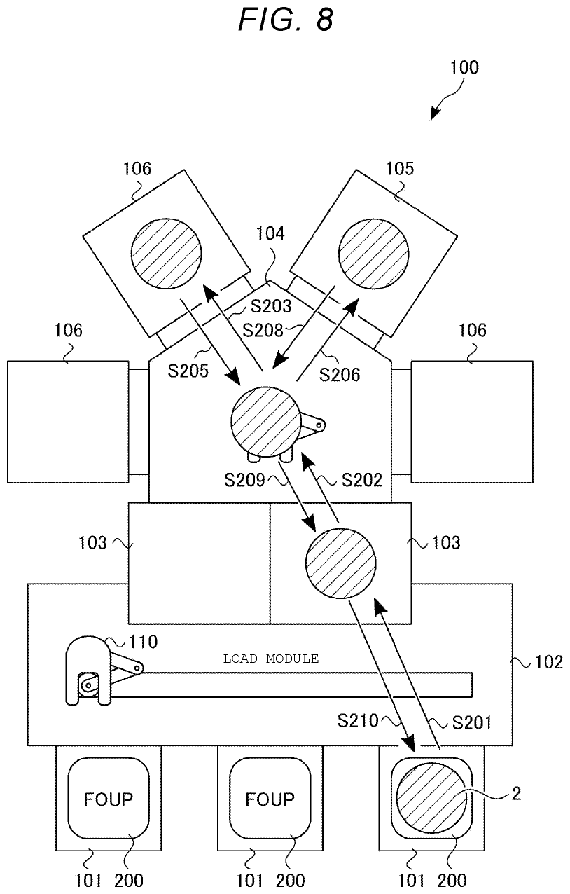

Next, an example of a flow of plasma processing in the semiconductor manufacturing apparatus 100 will be described with reference to FIGS. 7 and 8. FIG. 7 is a flowchart showing an example of the flow of plasma processing in the semiconductor manufacturing apparatus 100. FIG. 8 is an apparatus plan view showing movement of the semiconductor substrate 2 in the semiconductor manufacturing apparatus 100. Examples in FIGS. 7 and 8 show a case where the plasma processing is consecutively performed in the RIE chamber 106 and the bevel processing chamber 105 in this order.

As shown in FIGS. 7 and 8, the FOUP 200 accommodating the semiconductor substrate 2 is set in the load port 101 of the semiconductor manufacturing apparatus 100 (S200).

The control circuit 107 opens the FOUP 200. The handler 110 of the load module 102 is controlled to load the semiconductor substrate 2 into the load lock 103 (S201).

After the load lock 103 is vacuumed, the control circuit 107 controls the handler 120 of the transfer chamber 104 to convey the semiconductor substrate 2 inside the load lock 103 to the transfer chamber 104 (S202).

The control circuit 107 controls the handler 120 to convey the semiconductor substrate 2 to the RIE chamber 106 (S203).

The control circuit 107 performs the plasma processing on the front surface of the semiconductor substrate 2 in the RIE chamber 106 (S204). For example, when the film of the compound 2000 is formed on the front surface of the semiconductor substrate 2, the control circuit 107 performs the reduction processing using H₂ plasma to form the modified layer 3000 on the front surface of the semiconductor substrate 2.

The control circuit 107 controls the handler 120 to unload the semiconductor substrate 2 from the RIE chamber 106 to the transfer chamber 104 (S205).

The control circuit 107 controls the handler 120 to convey the semiconductor substrate 2 to the bevel processing chamber 105 (S206).

The control circuit 107 performs the plasma processing on the bevel of the semiconductor substrate 2 in the bevel processing chamber 105 (S207). Details of the processing in the bevel processing chamber 105 are the same as those in the first embodiment.

The control circuit 107 controls the handler 120 to unload the semiconductor substrate 2 from the bevel processing chamber 105 to the transfer chamber 104 (S208).

The control circuit 107 controls the handler 120 to convey the semiconductor substrate 2 to the load lock 103 (S209).

After the pressure of the load lock 103 returns to the atmospheric pressure, the control circuit 107 controls the handler 110 of the load module 102 to convey the semiconductor substrate 2 to the FOUP 200 (S210).

In the example in FIG. 7, a case has been described in which the processing in the RIE chamber 106 and the processing in the bevel processing chamber 105 are consecutively performed. Meanwhile, the present disclosure is not limited thereto. For example, after the processing in the bevel processing chamber 105 is performed, the processing in the RIE chamber 106 may be performed. Furthermore, the processing in RIE chamber 106 and the processing in bevel processing chamber 105 may not be consecutively performed. That is, after either the processing in the RIE chamber 106 or the processing in the bevel processing chamber 105 is performed, the semiconductor substrate 2 may be temporarily unloaded to the outside of the semiconductor manufacturing apparatus 100, and either the processing in the RIE chamber 106 or the processing in the bevel processing chamber 105 may be performed at another timing.

For example, after the plasma processing is performed on the upper surface and the bevel of the semiconductor substrate 2 by the semiconductor manufacturing apparatus 100, the wet etching described in S13 to S15 in FIG. 4 of the first embodiment is performed.

### 2.3 Advantageous Effects of Second Embodiment

A configuration according to the present embodiment can achieve the same advantageous effects as those in the first embodiment can be obtained.

### 3. Modification Examples

The semiconductor manufacturing apparatus according to the above-described embodiment includes the bevel processing chamber (11), the stage (12) provided in the bevel processing chamber, on which the substrate (2) is placed, and configured to come into contact with the first surface (back surface) of the substrate, the first gas supply pipe (SP1) configured to supply the first gas (CG1) for cooling the bevel of the substrate to the first surface side, first ring (13) surrounding the stage and having the outer diameter smaller than the diameter of the substrate, the top plate (14) provided in the bevel processing chamber and facing the second surface (surface) facing the first surface of the substrate, the second gas supply pipe (SP2) configured to supply the second gas (CG2) for cooling the bevel of the substrate to the second surface side, the second ring (15) surrounding the top plate and having the outer diameter smaller than the diameter of the substrate, the first electrode (16) surrounding the first ring, the second electrode (17) surrounding the second ring, the third gas supply pipe (SP3) configured to supply the process gas used for the plasma processing of the bevel, and the control circuit (40) that controls the plasma processing in the bevel.

The embodiments are not limited to the above-described forms, and various modifications can be made.

For example, in the above-described embodiment, a case where the substrate is the semiconductor substrate has been described. The substrate may be a substrate for heterogeneous computing, a substrate for micro electro mechanical systems (MEMS), a semiconductor wafer for three-dimensional integrated circuits, a substrate for biological and medical purposes, or a substrate for optical waveguides.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus comprising:
a bevel processing chamber;
a stage provided in the bevel processing chamber, on which a substrate is to be placed, and configured to come into contact with a first surface of the substrate;
a first gas supply pipe configured to supply a first gas to a first surface side of the substrate to cool a bevel of the substrate;
a first ring surrounding the stage and having an outer diameter smaller than a diameter of the substrate;
a top plate provided in the bevel processing chamber and facing a second surface of the substrate that is on an opposite side of the substrate with respect to the first surface;
a second gas supply pipe configured to supply a second gas to a second surface side of the substrate to cool the bevel of the substrate;
a second ring surrounding the top plate and having an outer diameter smaller than the diameter of the substrate;
a first electrode surrounding the first ring;
a second electrode surrounding the second ring;
a third gas supply pipe configured to supply a process gas used for plasma processing of the bevel; and
a control circuit that controls the plasma processing of the bevel.

2. The semiconductor manufacturing apparatus according to claim 1,
wherein a distance between the substrate and the top plate is smaller than a distance between the first electrode and the second electrode.

3. The semiconductor manufacturing apparatus according to claim 1,
wherein the first gas includes at least one gas selected from the group including helium (He), neon (Ne), and argon (Ar).

4. The semiconductor manufacturing apparatus according to claim 1,
wherein the first gas supply pipe is configured to supply the process gas.

5. The semiconductor manufacturing apparatus according to claim 1,
wherein the process gas includes at least one gas selected from the group including hydrogen (H₂), ammonia (NH₃), hydrogen sulfide (H₂S), water vapor (H₂O), hydrogen fluoride (HF), hydrogen chloride (HCl), hydrogen bromide (HBr), hydrogen iodide (HI), methane (CH₄), trifluoromethane (CHF₃), difluoromethane (CH₂F₂), and fluoromethane (CH₃F).

6. The semiconductor manufacturing apparatus according to claim 1,
wherein a temperature of the stage in the plasma processing is 0° C. or higher and 60° C. or lower.

7. The semiconductor manufacturing apparatus according to claim 1,
wherein the bevel is interposed between the first electrode and the second electrode.

8. The semiconductor manufacturing apparatus according to claim 1, further comprising:
an RIE chamber; and
a transfer chamber connected to the bevel processing chamber and the RIE chamber,
wherein the control circuit controls conveying the substrate to the bevel processing chamber, the RIE chamber, and the transfer chamber.

9. A method for manufacturing a semiconductor device, comprising:
loading a substrate having a first surface and a second surface on an opposite side of the first surface into a bevel processing chamber;
supplying a first gas for cooling a bevel of the substrate to the first surface side;
supplying a second gas for cooling the bevel to the second surface side;
supplying a process gas to the bevel after supplying the first gas and the second gas;
performing plasma processing on the bevel; and
unloading the substrate subjected to the plasma processing from the bevel processing chamber.

10. The method for manufacturing a semiconductor device according to claim 9,
wherein the first gas includes at least one gas selected from the group including helium (He), neon (Ne), and argon (Ar).

11. The method for manufacturing a semiconductor device according to claim 9,
wherein the process gas includes at least one gas selected from the group including hydrogen (H₂), ammonia (NH₃), hydrogen sulfide (H₂S), water vapor (H₂O), hydrogen fluoride (HF), hydrogen chloride (HCl), hydrogen bromide (HBr), hydrogen iodide (HI), methane (CH₄), trifluoromethane (CHF₃), difluoromethane (CH₂F₂), and fluoromethane (CH₃F).

12. The method for manufacturing a semiconductor device according to claim 9, further comprising:
loading the substrate into an RIE chamber.

13. The method for manufacturing a semiconductor device according to claim 12, further comprising:
loading the substrate into the bevel processing chamber after unloading the substrate from the RIE chamber.

14. The method for manufacturing a semiconductor device according to claim 13, further comprising:
loading the substrate into a processing tank for wet etching after unloading the substrate from the bevel processing chamber;
performing wet etching on the bevel; and
unloading the substrate from the processing tank.

15. The method for manufacturing a semiconductor device according to claim 14,
wherein a chemical solution used for the wet etching includes at least one selected from the group including hydrochloric acid (HCl), hydrofluoric acid (HF), hydrochloric acid (HCl), and nitric acid (HNO₃).

16. An apparatus for processing a bevel of a substrate, comprising:
a bevel processing chamber;
a stage provided in the bevel processing chamber, on which the substrate is to be placed;
a top plate provided in the bevel processing chamber and facing the stage;
a first gas supply pipe configured to supply a first cooling gas from below the substrate;
a second gas supply pipe configured to supply a second cooling gas from above the substrate;
a first ring surrounding the stage;
a second ring surrounding the top plate;
a first electrode surrounding the first ring;
a second electrode surrounding the second ring;
a third gas supply pipe configured to supply a process gas used for plasma processing of the bevel from above the substrate; and
a control circuit that controls the plasma processing of the bevel.

17. The apparatus according to claim 16, wherein a distance between the top plate and the stage is smaller than a distance between the first electrode and the second electrode.

18. The apparatus according to claim 16, further comprising:
a high frequency power source that generates plasma discharge between the first electrode and the second electrode during the plasma processing.

19. The apparatus according to claim 16, wherein the first gas supply pipe extends through the stage and the second gas supply pipe extends through the top plate.
